(19) United States
(12) Patent Application Publication
(10) Pub. No.: US 2007/0114670 A1
(43) Pub. Date: May 24, 2007

(54) Corrosion-resistant aluminum conductive material and process for producing the same

(75) Inventors: Hideki Shimada, Shizuoka (JP); Yoshihiro Taguchi, Shizuoka (JP); Ken Ebihara, Shizuoka (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignee: NIPPON LIGHT METAL COMPANY, LTD.,, Tokyo (JP)

(21) Appl. No.: 10/574,689

(22) PCT Filed: Oct. 14, 2003
(86) PCT No.: PCT/JP03/13115

§ 371 Date: Jan. 18, 2007

(51) Int. Cl. H01L 23/48

(52) U.S. Cl. 257/771

(57) ABSTRACT

This invention relates to a corrosion-resistant aluminum conductive material comprising an aluminum material consisting of aluminum or an aluminum alloy and a conductive film formed on the surface of said aluminum material wherein defects in the conductive film are substantially sealed off by a hot water treatment or a steam treatment and to a process for producing a corrosion-resistant aluminum conductive material which comprises forming a conductive film on the surface of an aluminum material and subjecting to a hot water treatment or a steam treatment thereby substantially sealing off defects in the conductive film. This invention makes it possible to substantially seal off the defects unavoidably developed on the surface of the conductive film without harming the excellent properties of the aluminum material and provide excellent corrosion resistance even when the thickness of the conductive film is small.

### FIELD OF TECHNOLOGY

This invention relates to an aluminum conductive material comprising an aluminum material consisting of aluminum or an aluminum alloy and a conductive film formed on the surface of said aluminum material and to a process for producing the same and, more particularly, this invention relates to a corrosion-resistant aluminum conductive material useful for a large number of electrode materials employed, for example, in lithium ion secondary batteries, aluminum electrolytic capacitors, direct electrolysis of drinking water for chlorine sterilization, electrolysis of water for the production of alkali ion water and acidic water and electrolytic treatments (anodizing, electrolytic coloring, electrophoretic deposition and the like) in the production of aluminum construction materials and to a process for producing the same.

### BACKGROUND TECHNOLOGY

Carbon electrodes, typically corrosion-resistant graphite electrodes, are used widely as electrodes in the electrolytic treatment, for example, in the electrolytic coloring of anodic oxide films on aluminum materials. However, carbon electrodes generally cause a great loss of electric power in the electrolytic treatment because of their relatively high electrical resistance and, in addition, they are formed with difficulty into electrodes of complex shape or electrodes in the form of thin foil because of their poor formability. Even if formable, they would incur a rise in production cost and, besides, they would be scarcely recyclable.

Now, as an electrode material free from these problems, it is conceivable to use an aluminum material that shows relatively low electrical resistance, causes a minimal loss of electric power, is lightweight and easily formable and is easily recyclable as well. However, an aluminum material tends to corrode readily electrochemically and shows poor corrosion resistance. For example, an aluminum material in the form of a plate or an extruded profile is used as a counter electrode (cathode) in the anodizing treatment and an etched aluminum foil is used as a foil-shaped cathode in an aluminum electrolytic capacitor; however, these aluminum materials find a limited use and their useful life is problematically short, one to three years as a counter electrode (cathode) in the anodizing treatment and five to eight years as an electrode in an aluminum electrolytic capacitor.

It is therefore conceivable to form a highly conductive and corrosion-resistant film of carbon or a noble metal such as gold and silver on the surface of an aluminum material in order to provide corrosion resistance without harming the excellent properties of the luminum material such as electrical conductivity, formability, lightweight and recyclability.

However, when an electrode material is produced by forming a conductive film on the surface of an aluminum material as described above, defects such as pinholes and cracks develop unavoidably in the conductive film when the film thickness is relatively small, say, 15 μm or less or occasionally 5 μm or less; when a defective electrode material is used in an electrolytic treatment or the like, the aluminum material beneath the conductive film becomes exposed to the electrolytic solution and starts to corrode from where such defects have developed and the desired corrosion resistance may not be obtained in some cases. Conversely, an attempt to solve the aforementioned corrosion problem by increasing the thickness of a conductive film markedly raises the production cost and the resultant increase in weight harms the property of lightweight which is characteristic of an aluminum material.

Examples of the electrode materials of the aforementioned kind produced by forming conductive films on the surface of aluminum materials are cited below: an electrode for a chemical battery formed by electrodepositing a granular electrode material on the surface of a conductive substrate such as aluminum (JP5-94,821 A); a positive electrode material for an electric double layer capacitor consisting of a current collector such as aluminum on which a polarizable electrode material mainly consisting of activated carbon is supported (JP9-55,342 A); a polarizable electrode formed by electrophoretically depositing a layer mainly consisting of activated carbon on a conductive substrate such as aluminum (JP9-74,052 A); an electrode material for a nonaqueous electrolytic secondary battery in which a conductive layer of graphite or carbon black is provided on a current collector such as aluminum and, in addition, a mixed slurry of an electrode active material and others is provided on the conductive layer (JP9-97,625 A); and an electrode material for an electric double layer capacitor consisting of a clad metal formed by cladding a base metal such as aluminum with a noble metal sch as gold and platinum (JP2002-373,830 A).

In any of the aforementioned cases, however, a conductive film must be formed in a thickness greater than is necessary on the surface of a conductive substrate or a current collector in order to produce an electrode material free of defects such as pinholes and cracks. As noted above, lighter weight and lower cost are sacrificed where importance is attached to long-term durability (long life). Conversely, long-term durability (long life) is sacrificed where importance is attached to lighter weight and lower cost. Hence, the requirements for long-term durability, lighter weight and lower cost cannot necessarily be satisfied simultaneously.

Focusing attention on a corrosion-resistant aluminum conductive material comprising an aluminum material and a conductive film formed on its surface and the production thereof with ease at low cost, the inventors of this invention have conducted extensive studies on how to solve the aforementioned corrosion problem due to defects such as pinholes and cracks developed in the conductive film when the film thickness is made as small as 15 μm or less or occasionally as small as 5 μm or less without harming the excellent properties of the aluminum material (electrical conductivity, formability, lightweight, recyclability and the like), found surprisingly that a treatment with hot water or steam substantially seals off the defects unavoidably developed in the conductive film and provides excellent corrosion resistance and completed this invention.

Accordingly, an object of this invention is to substantially seal off defects unavoidably developed in a conductive film formed on the surface of an aluminum material without harming the excellent properties of the aluminum material and to provide an aluminum conductive material displaying excellent corrosion resistance even when the thickness of the conductive film is small.

Another object of this invention is to provide a process for producing said corrosion-resistant aluminum conductive material at low cost.

### DISCLOSURE OF THE INVENTION

This invention relates to a corrosion-resistant aluminum conductive material comprising an aluminum material consisting of aluminum or an aluminum alloy and a conductive film formed on the surface of said aluminum material wherein defects in the conductive film are substantially sealed off by a hot water treatment or a steam treatment.

This invention further relates to a process for producing a corrosion-resistant aluminum conductive material comprising an aluminum material consisting of aluminum or an aluminum alloy and a conductive film formed on the surface of said aluminum material which comprises forming a conductive film on the surface of an aluminum material and then subjecting to a hot water treatment or a steam treatment thereby substantially sealing off defects in the conductive film.

According to this invention, an aluminum material consists of aluminum or an aluminum alloy and is not limited to any specific aluminum-based material; for example, a plate, an extruded profile or a foil made from high-purity aluminum (JIS H4170; 1N99) and a variety of aluminum alloys such as A1100, A5052 and A6063. Another example is a composite aluminum material in which a thin film of aluminum material is attached by sticking, vapor deposition, plating or the like to the surface of a substrate such as synthetic resin, ceramic, glass, non-aluminum metal, paper and fiber.

According to this invention, the aforementioned conductive film may be formed on the surface of an aluminum material by any means from any conductive material as long as the film is conductive, corrosion-resistant and resistant to hot water or steam to be used in the subsequent treatment; for example, a film of carbon, a film of a noble metal such as gold (Au), silver (Ag), platinum (Pt) and palladium (Pd), a conductive film of a material selected from composite oxides of silver, chromium nitride and a platinum group metal and composites of boron carbide and nickel, a conductive coating and a conductive resin. A variety of methods can be used for forming a conductive film on the surface of an aluminum material; for example, wet or dry plating, flame spraying, electrophoretic deposition and coating.

The thickness of the aforementioned conductive film is not restricted. However, the effect of this invention is produced markedly when the thickness of a conductive film is so small as to allow defects such as pinholes and cracks to develop unavoidably, that is, when the thickness is normally 15 μm or less, preferably 10 μm, more preferably 5 μm or less. When the film thickness exceeds 15 μm, the defects such as pinholes and cracks develop less, but the weight of the film increases that much and the property of lightweight of an aluminum material is damaged. Moreover, where a film of carbon or a noble metal is formed, the production cost rises markedly which is unsuitable for commercial production.

Of the defects such as pinholes and cracks developed unavoidably in the conductive film, the hot water treatment or the steam treatment of this invention aims at sealing off those defects which are large enough to allow water molecules to enter. Extremely small defects that do not allow entrance of water molecules are not important from the viewpoint of corrosion resistance and they are not worth being called defects.

According to this invention, a conductive film is formed on the surface of an aluminum material and the resulting aluminum conductive material is subjected to a hot water treatment or a steam treatment to substantially seal off the defects such as pinholes and cracks unavoidably developed in the conductive film. Here, “to substantially seal off” means the following; during the hot water treatment or the steam treatment, water molecules enter pinholes or cracks whose size allows entrance of water molecules, reach the aluminum material and react with aluminum to form a hydrate thereby substantially blocking the defects and insulating the aluminum material while extremely minute defects such as pinholes and cracks which resist entrance of water molecules are disregarded.

The hot water treatment or the steam treatment of this invention is performed as follows: an aluminum conductive material obtained by forming a conductive film on the surface of an aluminum material is immersed in hot water normally at 70° C. or above, preferably at 90° C. or above, or exposed to steam normally at 70° C. or above, preferably 100° C. or above, at atmospheric pressure or with application of pressure and kept in this condition for 5 minutes or more to form an aluminum hydrate such as bayerite (Al₂O₃.3H₂O) and boemite (Al₂O₃. H₂O) on the portions of the aluminum material which are exposed through defects such as pinholes and cracks, the aluminum hydrate thus formed seals off the defects in the conductive film, and the aluminum material is insulated from the outside. When the treating temperature is below 70° C., bayerite is formed preferentially and the desirable corrosion resistance may not be obtained in some cases.

Water to be used in the aforementioned hot water or steam treatment according to this invention has a pH preferably in the range of 3-12, more preferably in the range of 4-9, at 25° C.; when the pH is below 3 or above 12, the rate of formation of the aluminum hydrate becomes lower than the rate of the simultaneously occurring dissolution of aluminum and the formation of the aluminum hydrate becomes undesirably retarded.

Moreover, water to be used in the aforementioned hot water treatment contains 25 ppm or less, preferably 10 ppm or less, of phosphate ions expressed as phosphorus (P) [hereinafter referred to as phosphate ion concentration (P)] and 25 ppm or less, preferably 10 ppm or less, of silicate ions expressed as silicon (Si) [hereinafter referred to as silicate ion concentration (Si)]. When the phosphate ion concentration (P) in water exceeds 25 ppm, aluminum phosphate is formed and the formation of the hydrate is suppressed. Likewise, when the silicate ion concentration (Si) in water exceeds 25 ppm, aluminum silicate is formed and the formation of the hydrate is suppressed.

According to this invention, the aluminum conductive material obtained after the aforementioned hot water treatment or steam treatment exhibits excellent corrosion resistance and is used as it is, or after drying if necessary, in a variety of applications requiring electrode materials.

A corrosion-resistant aluminum conductive material produced according to this invention displays excellent corrosion resistance as the defects such as pinholes and cracks which develop unavoidably when the film is made as thin as 15 μm or less or occasionally as thin as 5 μm or less are substantially sealed off without harming the excellent properties of the aluminum material such as electrical conductivity, formability, lightweight and recyclability.

Moreover, according to the process of this invention, a corrosion-resistant aluminum conductive material can be produced easily at low cost by simply subjecting an aluminum conductive material having a conductive film on its surface to a hot water treatment or a steam treatment.

### PREFERRED EMBODIMENTS OF THE INVENTION

A preferred mode of practice of this invention will be described concretely below with reference to the accompanying examples and comparative examples.

The corrosion resistance, the electrical conductivity and the comprehensive performance were evaluated in the examples and comparative examples according to the following test methods.

[Evaluation of corrosion resistance]

The test specimen was placed in an aqueous solution of acetic acid at pH 3 opposite a platinum counter electrode, a silver-silver chloride electrode as a reference electrode was immersed in a saturated aqueous potassium chloride solution, the saturated aqueous potassium chloride solution was connected to the specimen by a salt bridge, the specimen, the platinum counter electrode and the silver-silver chloride reference electrode were connected to a pontentiostat (electrochemical measurement system HZ-3000 available from Hokuto Denko Corporation), then the potential of the specimen was scanned from the natural electrode potential to the oxygen-generating potential against the silver-silver chloride reference electrode on the anode side and the peak current flowing through the specimen electrode was measured and evaluated as polarization current (μA/cm²).

In evaluating the corrosion resistance on the basis of the polarization current, the corrosion resistance is judged poor when the polarization current exceeds 10 μA/cm² as the aluminum material starts to dissolve then. Good corrosion resistance is ensured when the polarization current is kept at 10 μA/cm² or less, preferably at 6 μA/cm² or less. In particular, where the intended use is an electrode material, the polarization current is kept at 5 μA/cm² or less, preferably at 3 μA/cm² or less.

[Evaluation of Electrical Conductivity]

A steel rod with a 4.5 R hemispherical tip as a contact probe was gently brought into contact with the surface of a conductive film under a load of 100 gf and the electrical resistance between the contact probe and the aluminum material beneath the conductive film was measured with a meter for measuring low resistance (Model 3540 for low resistance measurement available from Hioki E. E. Corporation). The specimen was judged conductive when the electrical resistance is 5Ω or less; the measurements were made 50 times and the electrical conductivity was evaluated on the basis of the number of times the specimen was judged conductive.

According to this method of evaluating the electrical conductivity, the specime is judged poorly conductive when the number of times the specimen was judged conductive is less than 25/50 because this means that the number of resistant areas is greater than that of conductive areas. Hence, good conductivity is ensured when the number of times the specimen is judged conductive is 30/50 or more, preferably 35/50 or more. In particular, this value is 40/50 or more, preferably 45/50 or more, when the material is intended for use as an electrode material.

[Evaluation of Comprehensive Performance]

In addition to the aforementioned evaluation of the corrosion resistance and electrical conductivity, the adhesiveness and economics were additionally evaluated in consideration of the cases where the corrosion-resistant conductive aluminum materials of this invention are applied to a variety of electrode materials. The comprehensive performance was evaluated with respect to the four items of corrosion resistance, electrical conductivity, adhesiveness and economics and the results were expressed as follows: ◯, satisfying the four items; Δ, satisfying three items inclusive of corrosion resistance and electrical conductivity; X, satisfying two items or less.

The corrosion-resistant aluminum conductive material was evaluated for the adhesiveness after it had been tested for the corrosion resistance and judged “satisfactory” when no peeling occurred in the conductive film or judged “not satisfactory” when peeling occurred.

### EXAMPLE 1

An aluminum plate (JIS H 4000; A5052) with a thickness of 0.5 mm was degreased, subjected to the zincate treatment, then electroplated with nickel to form a 2 μm-thick nickel film and finally electroplated with gold to form a 1 μm-thick gold film.

The electroplated aluminum plate was kept in hot water [pH, 5.5; phosphate ion concentration (P), 2 ppm; silicate ion concentration (Si), 1 ppm] at 100° C. for 30 minutes, pulled out of the hot water and dried to give a corrosion-resistant aluminum plate (corrosion-resistant aluminum conductive material).

A specimen, 50 mm in length and 50 mm in width, was cut from the corrosion-resistant aluminum plate, the potential of the specimen was polarized against a silver-silver chloride reference electrode by scanning the potential from 0 to 1000 mV and the peak current was measured as polarization current. The specimen gave a value of 5 μA/cm² and was confirmed to be highly corrosion-resistant.

Furthermore, the specimen which had been used in the evaluation of the corrosion resistance was tested for the electrical conductivity. The specimen was judged “conductive” in every one of 50 measurements and the corrosion-resistant aluminum plate was confirmed to show good electrical conductivity.

On the basis of the aforementioned evaluation of the corrosion resistance and electrical conductivity plus the additional evaluation of the adhesiveness and economics, the comprehensive performance was evaluated as ◯.

The results are shown in Table 1.

### EXAMPLE 2

An aluminum plate was degreased as in Example 1, the degreased aluminum plate as an anode and a carbon electrode as a cathode were arranged in one liter of 1-methyl-2-pyrrolidone containing 10 g of carbon black with an average particle diameter of 0.5 μm and 2 g of poly(vinylidene fluoride) and a voltage of 10 V was applied between the two electrodes for 1 minute to electrophoretically form a 1 μm-thick carbon film on the surface of the aluminum plate.

The aluminum plate after the electrophoretic treatment was kept in steam at 120° C. for 30 minutes to give a corrosion-resistant aluminum plate (corrosion-resistant aluminum conductive material).

The corrosion-resistant aluminum plate was evaluated for the corrosion resistance, electrical conductivity and comprehensive performance as in Example 1.

The results are shown in Table 1.

### EXAMPLE 3

A coating composition was prepared by mixing carbon black with an average particle diameter of 0.5 μm and poly(vinylidene fluoride) at a ratio of 1:1 in 1-methyl-2-pyrrolidone, the coating composition was applied to the surface of an aluminum plate degreased as in Example 1 and the carbon-coated aluminum plate was dried at 200° C. for 2 minutes to form a 1 μm-thick carbon film on the surface of the aluminum plate.

The carbon-coated aluminum plate was kept in steam at 120° C. for 30 minutes to give a corrosion-resistant aluminum plate (corrosion-resistant aluminum conductive material).

The corrosion-resistant aluminum plate was evaluated for the corrosion resistance, electrical conductivity and comprehensive performance as in Example 1

The results are shown in Table 1.

### EXAMPLE 4

A 1:3 mixture of methane and ethylene was introduced to the surface of an aluminum plate degreased as in Example 1 at a reduced pressure of 0.15 MPa and the mixed gas was subjected to glow discharge to deposit carbon to a thickness of 1 μm on the surface of the aluminum plate.

The aluminum plate after the CVD treatment was kept in steam at 120° C. for 30 minutes to give a corrosion-resistant aluminum plate (corrosion-resistant aluminum conductive material).

The corrosion-resistant aluminum plate was evaluated for the corrosion resistance, electrical conductivity and comprehensive performance as in Example 1.

The results are shown in Table 1.

### EXAMPLE 5

An aluminum plate was degreased as in Example 1 and platinum was flame-sprayed on the degreased aluminum plate by the electron beam evaporation technique to a film thickness of 3 μm at a reduced pressure of 1×10⁻⁶ Torr for 10 minutes.

The aluminum plate after the flame spraying of platinum spraying was kept in hot water [pH, 5.5; phosphate ion concentration (P), 2 ppm; silicate ion concentration (Si), 1 ppm] at 100° C. for 30 minutes, pulled out of the hot water and dried to give a corrosion-resistant aluminum plate (corrosion-resistant aluminum conductive material).

The corrosion-resistant aluminum plate was evaluated for the corrosion resistance, electrical conductivity and comprehensive performance as in Example 1

The results are shown in Table 1.

### EXAMPLE 6

A corrosion-resistant aluminum plate (corrosion-resistant aluminum conductive material) was prepared as in Example 1 with the exception of performing the hot water treatment in hot water [pH, 2; phosphate ion concentration (P), 2 ppm; silicate ion concentration (Si), 1 ppm] at 100° C. for 45 minutes and it was evaluated for the corrosion resistance, electrical conductivity and comprehensive performance as in Example 1.

The results are shown in Table 1.

### EXAMPLE 7

A corrosion-resistant aluminum plate (corrosion-resistant aluminum conductive material) was prepared as in Example 1 with the exception of performing the hot water treatment in hot water [pH, 2.5; phosphate ion concentration (P), 30 ppm in place of 2 ppm; silicate ion concentration (Si), 1 ppm] at 100° C. for 45 minutes and it was evaluated for the corrosion resistance, electrical conductivity and comprehensive performance as in Example 1.

The results are shown in Table 1.

### EXAMPLE 8

A corrosion-resistant aluminum plate (corrosion-resistant aluminum conductive material) was prepared as in Example 5 with the exception of performing the hot water treatment in hot water [pH, 5.5; phosphate ion concentration (P), 2 ppm; silicate ion concentration (Si), 1 ppm] at 60° C. for 60 minutes and it was evaluated for the corrosion resistance, electrical conductivity and comprehensive performance as in Example 1.

The results are shown in Table 1.

### COMPARATIVE EXAMPLES 1-4

The aluminum plates degreased and treated respectively by electroplating with nickel and gold, electrophoretic deposition of carbon, coating with carbon and CVD of carbon as in the aforementioned Examples 1-4 with the exception of omitting the subsequent hot water treatment or steam treatment were designated as the corrosion-resistant aluminum conductive materials of Comparative Examples 1-4 and they were evaluated for the corrosion resistance, electrical conductivity and comprehensive performance as in Example 1.

The results are shown in Table 1.

### COMPARATIVE EXAMPLE 5

A corrosion-resistant aluminum plate (corrosion-resistant aluminum conductive material) was prepared by forming an 8 μm-thick gold film by electroplating as in Example 1 without the subsequent hot water treatment and it was evaluated for the corrosion resistance, electrical conductivity and comprehensive performance as in Example 1.

The results are shown in Table 1.

### EXAMPLE 9

A corrosion-resistant aluminum plate (corrosion-resistant aluminum conductive material) was prepared as in Example 1 with the exception of performing nickel electroplating to a film thickness of 3 μm in place of electroplating nickel to a film thickness of 2 μm followed by electroplating gold to a film thickness of 1 μm and performing the steam treatment in steam [phosphate ion concentration (P), 2 ppm; silicate ion concentration (Si), 1 ppm] at 120° C. in place of the hot water treatment.

The corrosion-resistant aluminum plate was evaluated for the corrosion resistance, electrical conductivity and comprehensive performance as in Example 1 with the exception of scanning the potential of the specimen against the silver-silver chloride reference electrode from the natural electrode potential to 0 mV on the anode side.

The results are shown in Table 1.

### COMPARATIVE EXAMPLE 6

A corrosion-resistant aluminum plate (corrosion-resistant aluminum conductive material) was prepared as in Example 9 with the exception of omitting the steam treatment at 120° C. and it was evaluated for the corrosion resistance, electrical conductivity and comprehensive performance as in Example 9.

The results are shown in Table 1.

| | | | | Test for corrosion | | |
|---|---|---|---|---|---|---|
| | | | | resistance | Test for | |
| | | | Hot water treatment or steam | Polarization current | electrical | Comprehensive |
| | | Conductive film | treatment | (μA/cm²) | conductivity | evaluation |
| Example | 1 | EMP-Ni(2 μm) + EMP- | pH: 5.5, P: 2 ppm, Si: 1 ppm, | 5 | 50/50 | ∘ |
| | | Au(1 μm) | 100° C. + 30 minutes | | | |
| | 2 | EPT-C(1 μm) | P: 2 ppm, Si: 1 ppm, 120° C. + | 5 | 50/50 | ∘ |
| | | | 30 minutes | | | |
| | 3 | CST-C(1 μm) | P: 2 ppm, Si: 1 ppm, 120° C. + | 5 | 50/50 | ∘ |
| | | | 30 minutes | | | |
| | 4 | CVD-C(1 μm) | P: 2 ppm, Si: 1 ppm, 120° C. + | 5 | 50/50 | ∘ |
| | | | 30 minutes | | | |
| | 5 | FCT-Pt(3 μm) | pH: 5.5, P: 2 ppm, Si: 1 ppm, | 6 | 50/50 | ∘ |
| | | | 100° C. + 30 minutes | | | |
| | 6 | EMP-Ni(2 μm) + EMP- | pH: 2, P: 2 ppm, Si: 1 ppm, | 8 | 50/50 | ∘ |
| | | Au(1 μm) | 100° C. + 45 minutes | | | |
| | 7 | EMP-Ni(2 μm) + EMP- | pH: 2.5, P: 30 ppm, Si: 1 ppm, | 10 | 45/50 | ∘ |
| | | Au(1 μm) | 100° C. + 45 minutes | | | |
| | 8 | FCT-Pt(3 μm) | pH: 5.5, P: 2 ppm, Si: 1 ppm, | 9 | 50/50 | ∘ |
| | | | 60° C. + 60 minutes | | | |
| | 9 | EMP-Ni(3 μm) | P: 2 ppm, Si: 1 ppm, 120° C. + | 6 | 50/50 | ∘ |
| | | | 30 minutes | | | |
| Comparative | 1 | EMP-Ni(2 μm) + EMP- | Omitted | 650 | 10/50 | x |
| example | | Au(1 μm) | | | | |
| | 2 | EPT-C(1 μm) | Omitted | 700 | 20/50 | x |
| | 3 | CST-C(1 μm) | Omitted | 350 | 10/50 | x |
| | 4 | CVD-C(1 μm) | Omitted | 610 | 20/50 | x |
| | 5 | EMP-Ni(2 μm) + EMP- | Omitted | 6 | 50/50 | Δ |
| | | Au(8 μm) | | | | |
| | 6 | EMP-Ni(3 μm) | Omitted | 850 | 50/50 | x |

(Notes)
EMP-Ni: Electroplating with nickel,
EMP-Au: Electroplating with gold,
EPT-C: Electrophoretic deposition of carbon,
CST-C: Coating with carbon,
CVD-C: CVD of carbon,
FCT-Pt: Flame spraying of platinum,
pH: pH value,
P: Phosphate ion concentration (P),
Si: Silicate ion concentration (Si)

### INDUSTRIAL APPLICABILITY

This invention relates to an aluminum conductive material comprising an aluminum material and a conductive film formed on the surface of said aluminum material wherein the problem of corrosion due to defects such as pinholes and cracks developed unavoidably when the thickness of the conductive film is made relatively small can be solved with certainty by a simple hot water or steam treatment. This invention thus can provide an aluminum conductive material of excellent corrosion resistance without harming the distinguished properties of the aluminum material (electrical conductivity, formability, lightweight, recyclability and the like) and the corrosion-resistant aluminum conductive material has a high commercial value as it is useful for a variety of electrode materials requiring good electrical conductivity and corrosion resistance.

1. A corrosion-resistant aluminum conductive material comprising an aluminum material consisting of aluminum or an aluminum alloy and a conductive film formed on the surface of said aluminum material wherein defects in the conductive film are substantially sealed off by a hot water treatment or a steam treatment.

2. A corrosion-resistant aluminum conductive material as described in claim 1 wherein the conductive film is formed by any one of plating, flame spraying, electrophoresis and coating.

3. A corrosion-resistant aluminum conductive material as described in claim 1 wherein the conductive film has a thickness of 5 μm or less.

4. A corrosion-resistant aluminum conductive material as described in claim 1 wherein the hot water treatment or the steam treatment is performed by using water of 70° C. or above.

5. A corrosion-resistant aluminum conductive material as described in claim 1 wherein the hot water treatment or the steam treatment is performed by using water showing a pH in the range of 3-12 at 25° C.

6. A corrosion-resistant aluminum conductive material as described in claim 1 wherein the hot water treatment or the steam treatment is performed by using water showing a phosphate ion concentration of 25 ppm or less as phosphorus and a silicate ion concentration of 25 ppm or less as silicon.

7. A process for producing a corrosion-resistant aluminum conductive material comprising an aluminum material consisting of aluminum or an aluminum alloy and a conductive film formed on the surface of said aluminum material which comprises forming a conductive film on the surface of an aluminum material and then subjecting to a hot water treatment or a steam treatment thereby substantially sealing off defects in the conductive film.

8. A process for producing a corrosion-resistant aluminum conductive material as described in claim 7 wherein the conductive film is formed by any one of plating, flame spraying, electrophoresis and coating.

9. A process for producing a corrosion-resistant aluminum conductive material as described in claim 7 wherein the conductive film has a thickness of 5 μm or less.

10. A process for producing a corrosion-resistant aluminum conductive material as described in claim 7 wherein the hot water treatment or the steam treatment is performed by using water of 70° C. or above.

11. A process for producing a corrosion-resistant aluminum conductive material as described in claim 7 wherein the hot water treatment or the steam treatment is performed by using water showing a pH in the range of 3-12 at 25° C.

12. A process for producing a corrosion-resistant aluminum conductive material as described in claim 7 wherein the hot water treatment or the steam treatment is performed by using water showing a phosphate ion concentration of 25 ppm or less as phosphorus and a silicate ion concentration of 25 ppm or less as silicon.

13. A corrosion-resistant aluminum conductive material as described in claim 2 wherein the conductive film has a thickness of 5 μm or less.

14. A corrosion-resistant aluminum conductive material as described in claim 2 wherein the hot water treatment or the steam treatment is performed by using water of 70° C. or above.

15. A corrosion-resistant aluminum conductive material as described in claim 2 wherein the hot water treatment or the steam treatment is performed by using water showing a pH in the range of 3-12 at 25° C.

16. A corrosion-resistant aluminum conductive material as described in claim 2 wherein the hot water treatment or the steam treatment is performed by using water showing a phosphate ion concentration of 25 ppm or less as phosphorus and a silicate ion concentration of 25 ppm or less as silicon.

17. A process for producing a corrosion-resistant aluminum conductive material as described in claim 8 wherein the conductive film has a thickness of 5 μm or less.

18. A process for producing a corrosion-resistant aluminum conductive material as described in claim 8 wherein the hot water treatment or the steam treatment is performed by using water of 70° C. or above.

19. A process for producing a corrosion-resistant aluminum conductive material as described in claim 8 wherein the hot water treatment or the steam treatment is performed by using water showing a pH in the range of 3-12 at 25° C.

20. A process for producing a corrosion-resistant aluminum conductive material as described in claim 8 wherein the hot water treatment or the steam treatment is performed by using water showing a phosphate ion concentration of 25 ppm or less as phosphorus and a silicate ion concentration of 25 ppm or less as silicon.
